(19) United States
(12) Patent Application Publication
(10) Pub. No.: US 2025/0133675 A1
(43) Pub. Date: Apr. 24, 2025

(54) PREVENTING AIRFLOW BLOCKAGE UNDER A RAISED FLOOR

(71) Applicant: INTERNATIONAL BUSINESS MACHINES CORPORATION, ARMONK, NY (US)

(72) Inventors: JOHN S. WERNER, FISHKILL, NY (US); ARKADIY O. TSFASMAN, WAPPINGERS FALLS, NY (US); ROBERT WALSH, WALLKILL, NY (US)

(21) Appl. No.: 18/493,266

(22) Filed: Oct. 24, 2023

(51) Int. Cl. H05K 7/02; H05K 7/20

(52) U.S. Cl. CPC H05K 7/02; H05K 7/20745

(57) ABSTRACT

Methods, systems, and products for preventing airflow blockage under a raised floor includes: receiving sensor measurements from a plurality of sensors positioned under a raised floor of a data center, determining, based on the sensor measurements, a mapping of under-floor cabling, and identifying, based on the sensor measurements and the mapping of the under-floor cabling, an airflow blockage under the raised floor.

### BACKGROUND

### Field of the Disclosure

The field of the disclosure is data processing, or, more specifically, methods, systems, and products for preventing airflow blockage under a raised floor.

### Description Of Related Art

Raised floors are used to provide a space between the base or floor of a building and the support floor or platform which objects or components may rest. In the example of a data center, raised floors may support racks of computing systems, while allowing for cables or cooling equipment to be positioned under the raised floor. A data center may utilize cooling equipment, such as air cooling equipment, under the raised floor to provide cooling to computing systems above the raised floor by pushing cool air throughout the space under the raised floor and into the computing systems above. However, when there is too much cabling in one location under the raised floor, the cabling may block airflow to some computing systems, which can cause system overheating or otherwise negatively effect system performance.

### SUMMARY

Methods and systems for preventing airflow blockage under a raised floor according to various embodiments are disclosed in this specification. In accordance with one aspect of the present disclosure, a method of preventing airflow blockage under a raised floor may include receiving sensor measurements from a plurality of sensors positioned under a raised floor of a data center, determining, based on the sensor measurements, a mapping of under-floor cabling, and identifying, based on the sensor measurements and the mapping of the under-floor cabling, an airflow blockage under the raised floor.

In accordance with another aspect of the present disclosure, preventing airflow blockage under a raised floor may include an apparatus including: a processing device, and memory operatively coupled to the processing device, wherein the processing device executes instructions to: receive sensor measurements from a plurality of sensors positioned under a raised floor of a data center, determine, based on the sensor measurements, a mapping of under-floor cabling, and identify, based on the sensor measurements and the mapping of the under-floor cabling, an airflow blockage under the raised floor.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1 shows an example line drawing of a system in an environment configured for preventing airflow blockage under a raised floor in accordance with embodiments of the present disclosure.

FIG. 2 is a block diagram of an example computing environment configured for preventing airflow blockage under a raised floor according to some embodiments of the present disclosure.

FIG. 3 is a flowchart of an example method for preventing airflow blockage under a raised floor according to some embodiments of the present disclosure.

FIG. 4 is a flowchart of an example method for preventing airflow blockage under a raised floor according to some embodiments of the present disclosure.

FIG. 5 is a flowchart of an example method for preventing airflow blockage under a raised floor according to some embodiments of the present disclosure.

### DETAILED DESCRIPTION

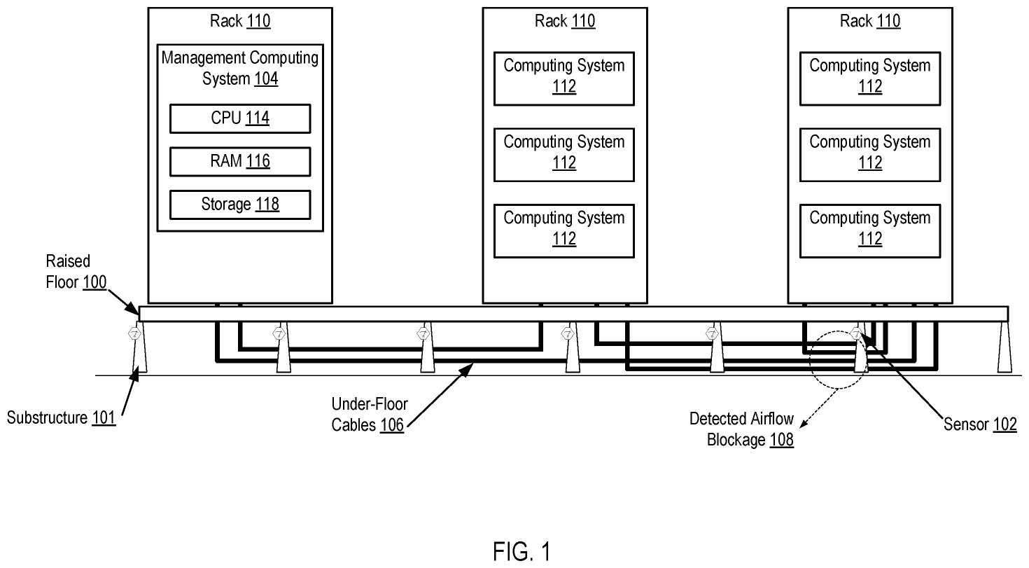

Exemplary methods, systems, and products for preventing airflow blockage under a raised floor in accordance with the present disclosure are described with reference to the accompanying drawings, beginning with FIG. 1. FIG. 1 sets forth an example line drawing of a management computing system implemented in an environment with a raised floor and configured for preventing airflow blockage under a raised floor in accordance with embodiments of the present disclosure. The example of FIG. 1 includes multiple racks (such as rack 110) each having one or more computing systems (such as management computing system 104 and computing system 112), a raised floor 100, substructure 101, one or more sensors (such as sensor 102), and under-floor cables 106.

The example raised floor 100 in FIG. 1 is configured to provide a space between the floor of the building and the floor on which equipment, such as computing systems or server racks, may rest on, where the space may be used for cabling (such as cables from the computing systems or racks), cooling components or infrastructure, and the like. In one embodiment, the raised floor 100 of FIG. 1 is a raised floor of a data center. In one embodiment, a data center may utilize HVAC (Heating, Ventilation, and Air Conditioning) equipment under the raised floor to provide cooling to computing systems above the raised floor by pushing cool air throughout the space under the raised floor and into the computing systems above. For example, computing systems 112 within racks 110 may be at least partially cooled by air flowing up from under the raised floor 100.

The example racks 110 and computing systems included within the racks may include under-floor cables 106 that passes between racks or systems under the raised floor 100. Such under-floor cables 106 may include power cables, communication cables, network cables, backup power cables, and the like. Different computing systems or racks may require different amounts of under-floor cabling and so different areas under the raised floor will have different amounts of under-floor cabling. Continuing with the example above, where computing systems 112 within racks 110 are partially cooled by air flowing up from under the raised floor 100, an increase in the amount of under-floor cabling at one location may cause an airflow blockage (i.e., a decrease in the amount of airflow to the systems proximate to that location. Decreased or restricted airflow to computing systems may cause such systems to experience a decrease in system performance, overheating, system failure, and the like. In FIG. 1, the airflow blockage 108 under the raised floor 100 may be caused by the increased amount of under-floor cabling present at that location, which may in turn negatively impact the computing systems surrounding that location.

The example management computing system 104 of FIG. 1 is a computing system configured to manage functions of the data center. The management computing system 104 of FIG. 1 includes a central processing unit (CPU) 114, random access memory (RAM) 116, and storage 118. The management computing system 104 may include DCIM (Data Center Infrastructure Management) software or other managing software configured to monitor or manage functions of the data center. In one exemplary embodiment of the present disclosure, the management computing system 104 is also configured to prevent, identify, and correct airflow blockages under the raised floor of the data center. Identifying, preventing, or correcting airflow blockages (such as detected airflow blockage 108) under the raised floor 100 may be carried out by the management computing system 104 based on data from sensors (such as sensor 102) positioned beneath the raised floor.

Example sensors 102 of FIG. 1 may include airflow sensors, weight sensors, pressure sensors, LIDAR or radar sensors (or other distance sensors), and the like. The sensors beneath the raised floor may all be the same type of sensor, or they may be multiple different sensor types includes beneath the raised floor. The sensors may be mounted to the underside of floor tiles included within the raised floor, to substructure 101 of the raised floor, or any other surface or structure beneath the raised floor 100. In one embodiment, sensors 102 may be positioned under the raised floor in a uniform pattern, such as at each supporting member of the raised floor substructure 101 (as shown in FIG. 1), every other supporting member, or some other pattern or configuration. In another embodiment, the sensors may be positioned based on the location of racks or computing systems above the raised floor. For example, sensors may be positioned beneath the raised floor at locations proximate to each rack 110 or computing system or may be positioned based on groups of racks or computing systems.

The management computing system 104 may receive measurements or sensor data from the sensors positioned under the raised floor. The sensor data received from the sensors may be used to determine a mapping of under-floor cabling beneath the raised floor. In an example with multiple airflow sensors positioned under the raised floor, the management computing system 104 creates a mapping of under-floor cabling by determining the amount of cabling at various positions under the raised floor based on an amount of airflow detected by the sensors at each of the various positions. In such an example, the amount of airflow detected by a sensor at the sensor's position would be decreased or restricted when more under-floor cables are present at that position. In another example with weight sensors positioned under the raised floor, the management computing system 104 creates a mapping of under-floor cabling by determining the amount of cabling at various positions under the raised floor based on a detected weight (such as the weight of the under-floor cables) at each of the various sensor positions. In another example with LIDAR sensors positioned under the raised floor, the management computing system 104 creates a mapping of under-floor cabling by detecting the position of the under-floor cables 106 at each of the various sensor positions using the LIDAR sensors. The management computing system 104 is configured to create a mapping of under-floor cabling based on sensor measurements from any combination of varying types of sensors.

The management computing system 104 of FIG. 1 is configured to identify airflow blockages under the raised floor. Identifying an airflow blockage may be carried out by the management computing system 104 based on one or more of the sensor measurements and the mapping of under-floor cabling. For example, identifying an airflow blockage based only on the mapping of under-floor cabling may be carried out by determining that there is a location under the raised floor that has an amount of cabling or a type of cabling that would restrict airflow at that location. In another example, identifying an airflow blockage based only on sensor measurements may be carried out by determining that an airflow rate (based on an airflow sensor measurement) is lower than a threshold amount indicative of an airflow blockage. In another example, identifying an airflow blockage based on both the mapping and sensor measurements may be carried out by verifying that a detected restricted airflow rate from a sensor corresponds with the presence of a threshold amount of under-floor cabling in the mapping in order to determine that an airflow blockage exists that is caused by the under-floor cabling. In the example of FIG. 1, the management computing system 104 identifies an airflow blockage 108 at sensor 102 based on a created mapping of the under-floor cables 106 and based on sensor measurements from sensor 102.

The management computing system is configured to monitor the mapping of the under-floor cabling and update the mapping based on updated sensor measurements. In one embodiment, the management computing system 104 may obtain updated sensor measurements periodically for updating the mapping. In another embodiment, the management computing system 104 may obtain updated sensor measurements for updating the mapping whenever under-floor cabling is added under the raised floor.

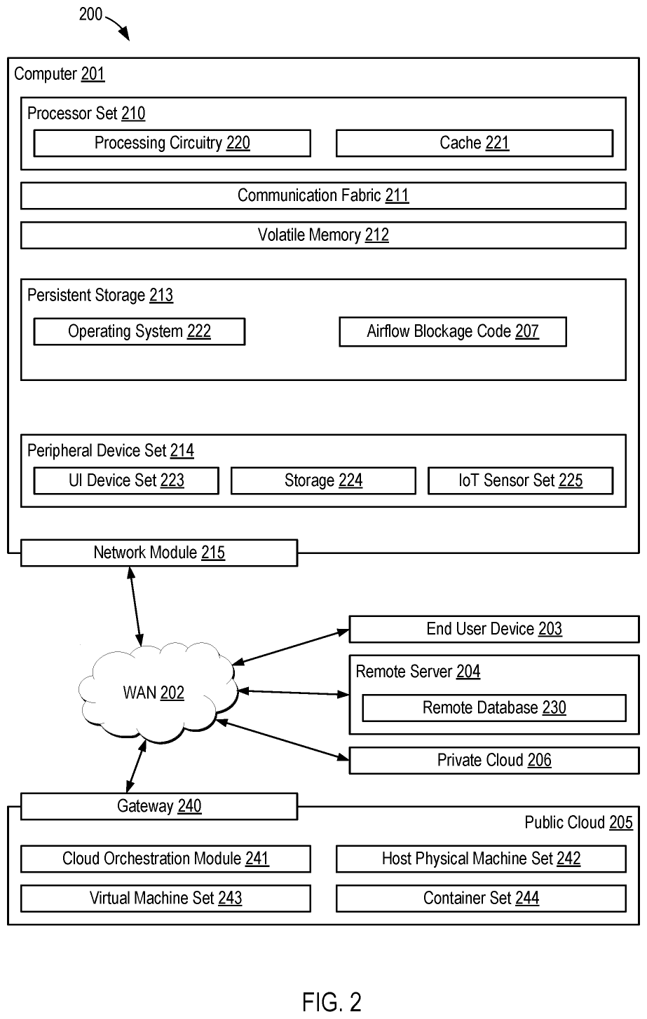

For further explanation, FIG. 2 sets forth a block diagram of computing environment 200 configured for preventing airflow blockage under a raised floor in accordance with embodiments of the present disclosure. Computing environment 200 contains an example of an environment for the execution of at least some of the computer code involved in performing the inventive methods, such as airflow blockage code 207. In addition to airflow blockage code 207, computing environment 200 includes, for example, computer 201, wide area network (WAN) 202, end user device (EUD) 203, remote server 204, public cloud 205, and private cloud 206. In this example embodiment, computer 201 is the management computing system 104 of FIG. 1, and includes processor set 210 (including processing circuitry 220 and cache 221), communication fabric 211, volatile memory 212, persistent storage 213 (including operating system 222 and airflow blockage code 207, as identified above), peripheral device set 214 (including user interface (UI) device set 223, storage 224, and Internet of Things (IoT) sensor set 225), and network module 215. Remote server 204 includes remote database 230. Public cloud 205 includes gateway 240, cloud orchestration module 241, host physical machine set 242, virtual machine set 243, and container set 244.

Computer 201 may take the form of a desktop computer, laptop computer, tablet computer, smart phone, mainframe computer, quantum computer or any other form of computer or mobile device now known or to be developed in the future that is capable of running a program, accessing a network or querying a database, such as remote database 230. As is well understood in the art of computer technology, and depending upon the technology, performance of a computer-implemented method may be distributed among multiple computers and/or between multiple locations. On the other hand, in this presentation of computing environment 200, detailed discussion is focused on a single computer, specifically computer 201, to keep the presentation as simple as possible. Computer 201 may be located in a cloud, even though it is not shown in a cloud in FIG. 2. On the other hand, computer 201 is not required to be in a cloud except to any extent as may be affirmatively indicated.

Processor set 210 includes one, or more, computer processors of any type now known or to be developed in the future. Processing circuitry 220 may be distributed over multiple packages, for example, multiple, coordinated integrated circuit chips. Processing circuitry 220 may implement multiple processor threads and/or multiple processor cores. Cache 221 is memory that is located in the processor chip package(s) and is typically used for data or code that should be available for rapid access by the threads or cores running on processor set 210. Cache memories are typically organized into multiple levels depending upon relative proximity to the processing circuitry. Alternatively, some, or all, of the cache for the processor set may be located “off chip.” In some computing environments, processor set 210 may be designed for working with qubits and performing quantum computing.

Computer readable program instructions are typically loaded onto computer 201 to cause a series of operational steps to be performed by processor set 210 of computer 201 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 221 and the other storage media discussed below. The program instructions, and associated data, are accessed by processor set 210 to control and direct performance of the inventive methods. In computing environment 200, at least some of the instructions for performing the inventive methods may be stored in airflow blockage code 207 in persistent storage 213.

Communication fabric 211 is the signal conduction path that allows the various components of computer 201 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 212 is any type of volatile memory now known or to be developed in the future. Examples include dynamic type random access memory (RAM) or static type RAM. Typically, volatile memory 212 is characterized by random access, but this is not required unless affirmatively indicated. In computer 201, the volatile memory 212 is located in a single package and is internal to computer 201, but, alternatively or additionally, the volatile memory may be distributed over multiple packages and/or located externally with respect to computer 201.

Persistent storage 213 is any form of non-volatile storage for computers that is now known or to be developed in the future. The non-volatility of this storage means that the stored data is maintained regardless of whether power is being supplied to computer 201 and/or directly to persistent storage 213. Persistent storage 213 may be a read only memory (ROM), but typically at least a portion of the persistent storage allows writing of data, deletion of data and re-writing of data. Some familiar forms of persistent storage include magnetic disks and solid state storage devices. Operating system 222 may take several forms, such as various known proprietary operating systems or open source Portable Operating System Interface-type operating systems that employ a kernel. The code included in airflow blockage code 207 typically includes at least some of the computer code involved in performing the inventive methods.

Peripheral device set 214 includes the set of peripheral devices of computer 201. Data communication connections between the peripheral devices and the other components of computer 201 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 223 may include components such as a display screen, speaker, microphone, wearable devices (such as goggles and smart watches), keyboard, mouse, printer, touchpad, game controllers, and haptic devices. Storage 224 is external storage, such as an external hard drive, or insertable storage, such as an SD card. Storage 224 may be persistent and/or volatile. In some embodiments, storage 224 may take the form of a quantum computing storage device for storing data in the form of qubits. In embodiments where computer 201 is required to have a large amount of storage (for example, where computer 201 locally stores and manages a large database) then this storage may be provided by peripheral storage devices designed for storing very large amounts of data, such as a storage area network (SAN) that is shared by multiple, geographically distributed computers. IoT sensor set 225 is made up of sensors that can be used in Internet of Things applications. For example, one sensor may be a thermometer and another sensor may be a motion detector.

Network module 215 is the collection of computer software, hardware, and firmware that allows computer 201 to communicate with other computers through WAN 202. Network module 215 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 215 are performed on the same physical hardware device. In other embodiments (for example, embodiments that utilize software-defined networking (SDN)), the control functions and the forwarding functions of network module 215 are performed on physically separate devices, such that the control functions manage several different network hardware devices. Computer readable program instructions for performing the inventive methods can typically be downloaded to computer 201 from an external computer or external storage device through a network adapter card or network interface included in network module 215. Network module 215 may be configured to communicate with other systems or devices, such as sensors 102, for receiving sensor measurements.

WAN 202 is any wide area network (for example, the internet) capable of communicating computer data over non-local distances by any technology for communicating computer data, now known or to be developed in the future. In some embodiments, the WAN 202 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 203 is any computer system that is used and controlled by an end user (for example, a customer of an enterprise that operates computer 201), and may take any of the forms discussed above in connection with computer 201. EUD 203 typically receives helpful and useful data from the operations of computer 201. For example, in a hypothetical case where computer 201 is designed to provide a recommendation to an end user, this recommendation would typically be communicated from network module 215 of computer 201 through WAN 202 to EUD 203. In this way, EUD 203 can display, or otherwise present, the recommendation to an end user. In some embodiments, EUD 203 may be a client device, such as thin client, heavy client, mainframe computer, desktop computer and so on.

Remote server 204 is any computer system that serves at least some data and/or functionality to computer 201. Remote server 204 may be controlled and used by the same entity that operates computer 201. Remote server 204 represents the machine(s) that collect and store helpful and useful data for use by other computers, such as computer 201. For example, in a hypothetical case where computer 201 is designed and programmed to provide a recommendation based on historical data, then this historical data may be provided to computer 201 from remote database 230 of remote server 204.

Public cloud 205 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 205 is performed by the computer hardware and/or software of cloud orchestration module 241. The computing resources provided by public cloud 205 are typically implemented by virtual computing environments that run on various computers making up the computers of host physical machine set 242, which is the universe of physical computers in and/or available to public cloud 205. The virtual computing environments (VCEs) typically take the form of virtual machines from virtual machine set 243 and/or containers from container set 244. It is understood that these VCEs may be stored as images and may be transferred among and between the various physical machine hosts, either as images or after instantiation of the VCE. Cloud orchestration module 241 manages the transfer and storage of images, deploys new instantiations of VCEs and manages active instantiations of VCE deployments. Gateway 240 is the collection of computer software, hardware, and firmware that allows public cloud 205 to communicate through WAN 202.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 206 is similar to public cloud 205, except that the computing resources are only available for use by a single enterprise. While private cloud 206 is depicted as being in communication with WAN 202, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 205 and private cloud 206 are both part of a larger hybrid cloud.

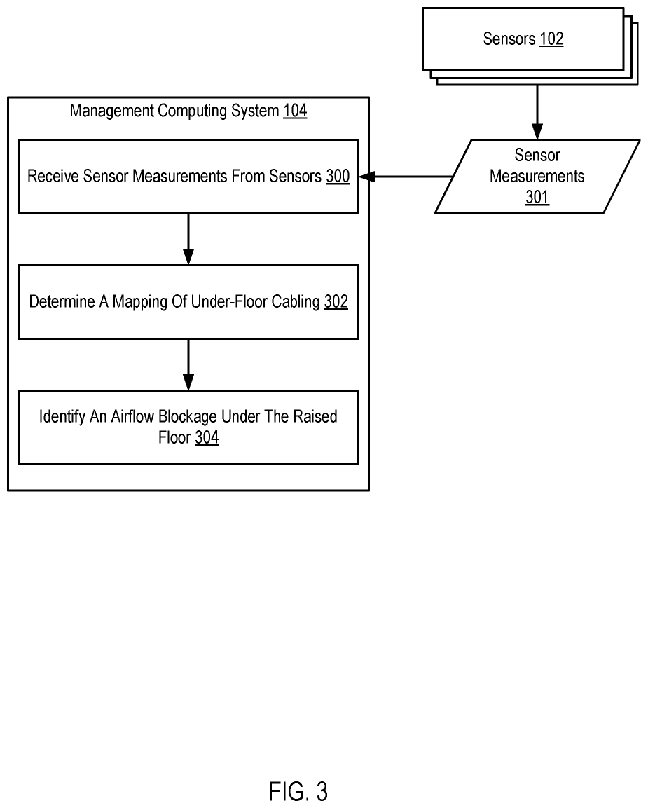

For further explanation, FIG. 3 sets forth a flow chart illustrating an exemplary method of preventing airflow blockage under a raised floor according to embodiments of the present disclosure. The method of FIG. 3 includes receiving 300 sensor measurements from sensors. Receiving sensor measurements 301 from sensors 102 may be carried out by management computing system 104 over a network, such as a wireless network. The sensor measurements 301 may include sensor data measured by the one or more sensors, where the sensor measurements may include an indication of a sensor type, a time the sensor data was obtained by the sensor, which sensor each sensor data is from (which may be used to determine the location under the raised floor corresponding to each of the sensor measurements), and the like. In one example, sensor measurements may include airflow measurements from one or more airflow sensors, the airflow measurements including an airflow rate and a direction of airflow. In another example, the sensor measurements may include one or more other types of sensor measurements.

The method of FIG. 3 also includes determining 302 a mapping of under-floor cabling. Determining a mapping of under-floor cabling may be carried out by management computing system 104 analyzing the received sensor measurements 301 and determining the positioning of cables under the raised floor. The mapping may include the cable routes of each individual under-floor cable below the raised floor, along with the cable's positioning and cable type. In another embodiment, the mapping may indicate the amount of cabling at various positioned under the raised floor. In another embodiment, the management computing system 104 may also create an airflow mapping based on multiple airflow sensor measurements. Such an airflow mapping may be compared with the mapping of under-floor cabling to determine how under-floor cables are affecting airflow. Comparing these two mappings may include identifying potential airflow blockages, partial airflow blockages, or full airflow blockages.

The method of FIG. 3 also includes identifying 304 an airflow blockage under the raised floor. Identifying 304 an airflow blockage under the raised floor may be carried out by management computing system 104 based on one or more of the received sensor measurements 301 and the mapping of under-floor cabling. For example, identifying an airflow blockage based on the mapping of under-floor cabling may be carried out by determining that there is a location under the raised floor that has an amount of cabling or a type of cabling that would restrict airflow at that location. In another example, identifying an airflow blockage based on sensor measurements may be carried out by determining that an airflow rate (based on an airflow sensor measurement) is lower than a threshold amount indicative of an airflow blockage. In another example, identifying an airflow blockage based on both the mapping and sensor measurements may be carried out by verifying that a detected restricted airflow rate from a sensor corresponds with the presence of a threshold amount of under-floor cabling in the mapping in order to determine that an airflow blockage exists that is caused by the under-floor cabling.

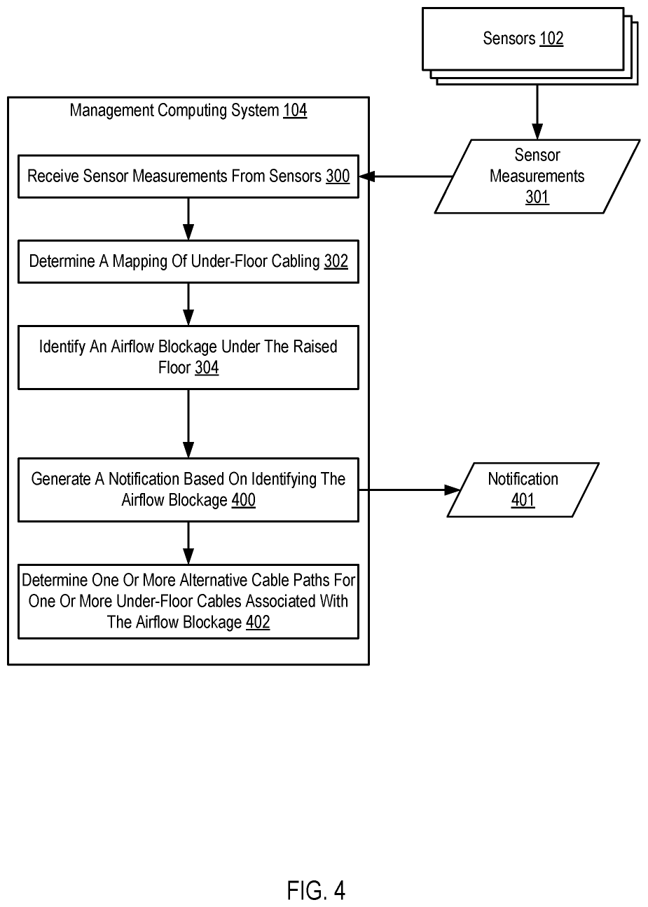

For further explanation, FIG. 4 sets forth a flow chart illustrating another exemplary method of preventing airflow blockage under a raised floor according to embodiments of the present disclosure. The method of FIG. 4 includes generating 400 a notification based on identifying the airflow blockage. Generating 400 a notification 401 may be carried out by management computing system 104 in response to identifying the airflow blockage. Notification 401 may be generated and stored in memory local to the management computing system 104 or in remote memory in order to later be viewed. In another embodiment, the notification may be sent to another computing system or device, whether over a wired connection or a wireless connection, such as over a network. The notification may include one or more of an indication that an airflow blockage was identified, a position under the raised floor where the airflow blockage is identified, identification of the one or more sensors used to identify the blockage, an indication of specific under-floor cables (along with their routes and any connected computing systems or racks) associated with the identified airflow blockage, and the like.

The method of FIG. 4 also includes determining 402 one or more alternative cable paths for one or more under-floor cables associated with the airflow blockage. Determining 402 one or more alternative cable paths for one or more under-floor cables associated with the airflow blockage may be carried out by management computing system 104 based on the mapping of under-floor cabling. The management computing system 104 may implement artificial intelligence or some other code or program in such a determination. In one embodiment, in determining 402, management computing system 104 uses the mapping of under-floor cabling to determine which specific under-floor cables are associated with the identified airflow blockage. Management computing system 104 may further determine which under-floor cables, and how many, to reroute in order to remove the airflow blockage.

In another embodiment, determining one or more alternative cable paths for one or more under-floor cables associated with the airflow blockage may include calculating a score for each of the one or more alternative cable paths based on one or more of: workloads associated with each of the one or more under-floor cables, a determination of whether a system associated with each of the one or more under-floor cables comprises backup power cables. In scoring each potential alternative cable path, an alternative cable path with the best score may be selected that fixes the airflow blockage while avoiding high risk actions or potential malfunctions. For example, management computing system 104 may take into account which workloads (and the importance of such workloads) are being executed on systems associated with each of the one or more under-floor cables associated with the airflow blockage, making note of which systems are regularly, or currently, executing higher priority workloads. In such an example, it may be advantageous to avoid moving a cable connected to a system executing very high priority workloads when considering alternative cable paths, so as to avoid potentially messing up the system executing high priority workloads. In another example, management computing system 104 may take into account whether back-up cables exist for systems associated with each of the one or more under-floor cables associated with the airflow blockage. In such an example, it may be advantageous to avoid moving a cable, such as a power cable, that is connected to a system that does not have other backup power cables, so as to avoid potentially removing power to the system. One or more alternative cable paths may be selected automatically (such as by management computing system 104) based on the score of each of the cable paths, or a user may select the one or more alternative cable paths.

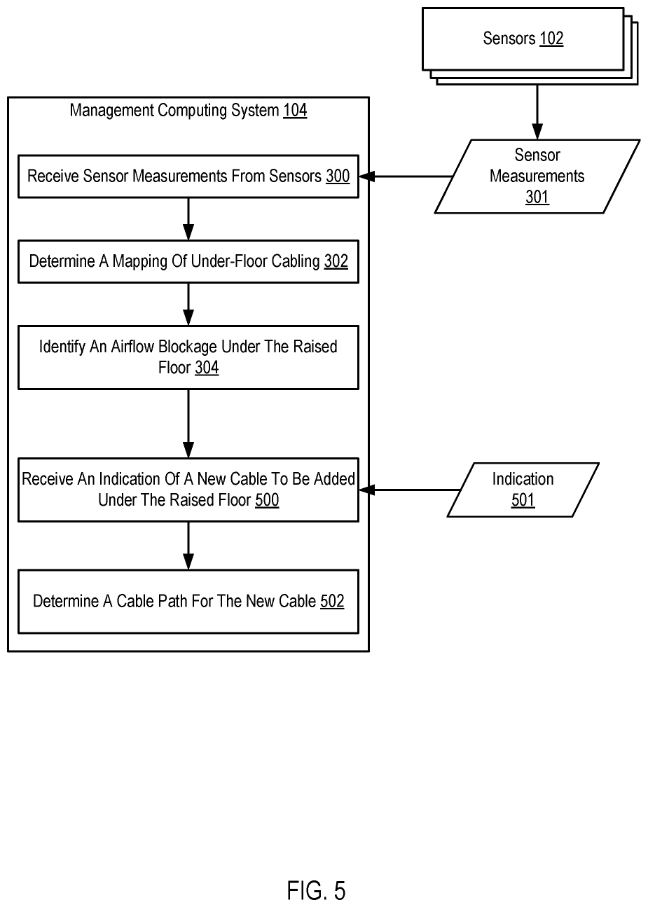

For further explanation, FIG. 5 sets forth a flow chart illustrating another exemplary method of preventing airflow blockage under a raised floor according to embodiments of the present disclosure. The method of FIG. 5 includes receiving 500 an indication of a new cable to be added under the raised floor. Receiving 500 an indication of a new cable to be added under the raised floor may be carried out by management computing system 104 receiving the indication 501 from another computing system, such as over a network. The indication 501 may include a position of two endpoints for the new cable. The indication may also include an indication of one or more of a cable type, a cable size, specific computing systems at the two endpoints, and the like.

The method of FIG. 5 also includes determining 502 a cable path for the new cable. Determining 502 a cable path for the new cable may be carried out by management computing system 104 based on the two endpoints included in the indication 501 and on the mapping of under-floor cabling. For example, the management computing system 104 may use the mapping of under-floor cabling to determine which cable paths for the new cable will not cause a potential airflow blockage, and then select a cable path from those determined cable paths. In one embodiment, the determined cable path for the new cable includes a cable length and a cable placement under the raised floor, indicating where to place each part of the new cable under the raised floor. The management computing system 104 may implement artificial intelligence or some other code or program in such a determination.

In view of the explanations set forth above, readers will recognize that the benefits of preventing airflow blockage under a raised floor according to embodiments of the present disclosure include:
Increasing data center performance by decreasing potential airflow restrictions under the raised floor, thereby decreasing system errors caused by faulty cooling.
Increasing data center management by allowing for monitoring of airflow blockages and providing a means to fix any identified airflow blockages.
Increased efficiency when adding cables under a raised floor by avoiding potential cable routes that could cause airflow blockages.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. A method for preventing airflow blockage under a raised floor, comprising:
obtaining sensor measurements from a plurality of sensors positioned under a raised floor of a data center;
determining, based on the sensor measurements, a mapping of under-floor cabling; and
detecting, based on the sensor measurements and the mapping of the under-floor cabling, an airflow blockage under the raised floor.

2. The method of claim 1, further comprising generating a notification based on detecting the airflow blockage.

3. The method of claim 1, further comprising determining, based on the mapping of the under-floor cabling, one or more alternative cable paths for one or more under-floor cables associated with the airflow blockage.

4. The method of claim 3, including calculating a score for each of the one or more alternative cable paths based on one or more of: workloads associated with each of the one or more under-floor cables, a determination of whether a system associated with each of the one or more under-floor cables comprises backup power cables.

5. The method of claim 1, further comprising:
receiving an indication of a new cable to be added under the raised floor, the indication including a position of two endpoints for the new cable; and
determining, based on the two endpoints and the mapping of the under-floor cabling, a cable path for the new cable.

6. The method of claim 5, wherein the cable path for the new cable includes a cable length and a cable placement under the raised floor.

7. The method of claim 1, wherein the plurality of sensors comprises at least one airflow sensor.

8. The method of claim 1, wherein the plurality of sensors comprises at least one weight sensor.

9. The method of claim 1, wherein the plurality of sensors comprises at least one radar sensor.

10. The method of claim 1, wherein the plurality of sensors is positioned under the raised floor in a uniform pattern across the raised floor.

11. The method of claim 1, wherein the plurality of sensors is positioned under the raised floor based on a position of one or more computing systems located above the raised floor.

12. An apparatus comprising:
a processing device; and
memory operatively coupled to the processing device, wherein the processing device executes instructions to:
receive sensor measurements from a plurality of sensors positioned under a raised floor of a data center;
determine, based on the sensor measurements, a mapping of under-floor cabling; and
identify, based on the sensor measurements and the mapping of the under-floor cabling, an airflow blockage under the raised floor.

13. The apparatus of claim 12, wherein the processing device further executes instructions to generate a notification based on identifying the airflow blockage.

14. The apparatus of claim 12, wherein the processing device further executes instructions to determine, based on the mapping of the under-floor cabling, one or more alternative cable paths for one or more under-floor cables associated with the airflow blockage.

15. The apparatus of claim 12, wherein the processing device further executes instructions to:
receive an indication of a new cable to be added under the raised floor, the indication including a position of two endpoints for the new cable; and
determine, based on the two endpoints and the mapping of the under-floor cabling, a cable path for the new cable.

16. The apparatus of claim 12, wherein the plurality of sensors are mounted on a substructure of the raised floor.

17. A computer program product comprising a computer readable storage medium and computer program instructions stored therein that, when executed, are configured to:
receive sensor measurements from a plurality of sensors positioned under a raised floor of a data center;
determine, based on the sensor measurements, a mapping of under-floor cabling; and
identify, based on the sensor measurements and the mapping of the under-floor cabling, an airflow blockage under the raised floor.

18. The computer program product of claim 17, wherein the computer program instructions are further configured to generate a notification based on identifying the airflow blockage.

19. The computer program product of claim 17, wherein the computer program instructions are further configured to determine, based on the mapping of the under-floor cabling, one or more alternative cable paths for one or more under-floor cables associated with the airflow blockage.

20. The computer program product of claim 17, wherein the computer program instructions are further configured to:
receive an indication of a new cable to be added under the raised floor, the indication including a position of two endpoints for the new cable; and
determine, based on the two endpoints and the mapping of the under-floor cabling, a cable path for the new cable.
